(19) United States
(12) Patent Application Publication
(10) Pub. No.: US 2011/0261978 A1
(43) Pub. Date: Oct. 27, 2011

(54) Electronic Apparatus

(76) Inventor: Makoto Yamaguchi, Sagamihara-shi (JP)

(21) Appl. No.: 13/090,027

(22) Filed: Apr. 19, 2011

(30) Foreign Application Priority Data
Apr. 23, 2010 (JP) 2010-100114

(51) Int. Cl. H03F 99/00

(52) U.S. Cl. 381/120

(57) ABSTRACT

According to one embodiment, an electronic apparatus includes a speaker, a terminal, a first detector, a second detector, an amplifier, a power supply circuit and a control module. The terminal is configured to connect an external device via a connection member, the external device outputting an audio signal. The first detector is configured to detect that the connection member is connected to the terminal. The second detector is configured to detect that the audio signal is received via the terminal. The amplifier is configured to amplify the audio signal and to produce sound from the speaker. The controller is configured to control the power supply circuit to supply power to the amplifier, when the first detector detects that the connection member is connected to the terminal, the second detector detects that the audio signal is received, and the electronic apparatus is in an inoperative state.

### CROSS-REFERENCE TO RELATED APPLICATIONS

This application is based upon and claims the benefit of priority from Japanese Patent Application No. 2010-100114, filed Apr. 23, 2010; the entire contents of which are incorporated herein by reference.

### FIELD

Embodiments described herein relate generally to an electronic apparatus including a speaker.

### BACKGROUND

Conventionally, there is known an AV apparatus which can execute, when the insertion/removal of a plug in/from a terminal which receives an audio signal from the outside has been detected, various processes by using the insertion/removal of the plug as an effective trigger. In this conventional AV apparatus, for example, when the plug has been inserted in a mobile audio terminal, an audio signal which is input from a mobile audio can be output as an audio output signal of the AV apparatus.

In the conventional AV apparatus (e.g. a TV receiver), when the plug is inserted in the mobile audio terminal in a normal operative state in which video or audio can be output, the audio from the mobile audio can be output. In an inoperative state in which power is turned off, the audio from the mobile audio cannot be output.

In addition, in the conventional AV apparatus, the audio output function is activated by determining that the insertion of the plug in the mobile audio terminal is the indication of the user's intention to switch the input source. Thus, it is possible that the audio output function is activated simply by the insertion of the plug, leading to wasteful power consumption.

### BRIEF DESCRIPTION OF THE DRAWINGS

A general architecture that implements the various features of the embodiments will now be described with reference to the drawings. The drawings and the associated descriptions are provided to illustrate the embodiments and not to limit the scope of the invention.

FIG. 1 is an exemplary external appearance view showing the structure of an electric apparatus according to an embodiment;

FIG. 2 is an exemplary block diagram showing the system configuration of a personal computer according to the embodiment;

FIG. 3 is an exemplary view showing the relationship between a status signal, which is output from a determination circuit, and the ON/OFF of an audio output function in the embodiment; and

FIG. 4 is an exemplary flow chart illustrating an operation in a case of executing a monitoring process in an EC/KBC in the embodiment.

### DETAILED DESCRIPTION

Various embodiments will be described hereinafter with reference to the accompanying drawings.

In general, according to one embodiment, an electronic apparatus comprises a speaker, a terminal, a first detector, a second detector, an amplifier, a power supply circuit and a control module. The terminal is configured to connect an external device via a connection member, the external device outputting an audio signal. The first detector is configured to detect that the connection member is connected to the terminal. The second detector is configured to detect that the audio signal is received via the terminal. The amplifier is configured to amplify the audio signal and to produce sound from the speaker. The power supply circuit is configured to supply power to the amplifier. The controller is configured to control the power supply circuit to supply power to the amplifier, when the first detector detects that the connection member is connected to the terminal, the second detector detects that the audio signal is received, and the electronic apparatus is in an inoperative state.

An embodiment will now be described with reference to the accompanying drawings.

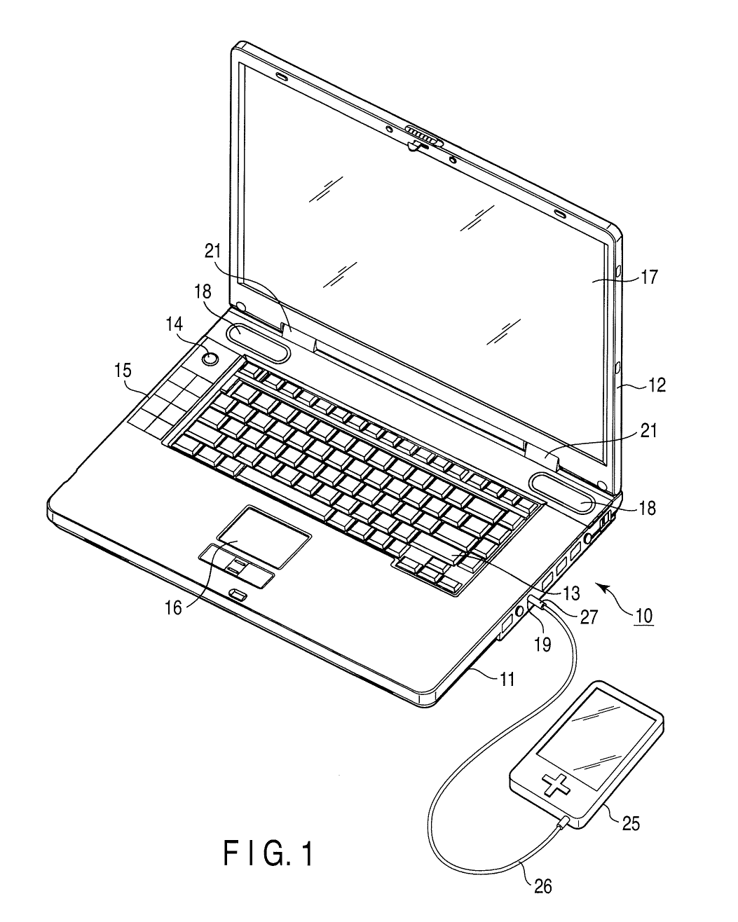

FIG. 1 an exemplary external appearance view showing the structure of an electronic apparatus according to the embodiment. The electronic apparatus is realized, for example, as a notebook-type portable personal computer 10. The personal computer 10 of this embodiment has an audio output function (sleep & music function) for receiving, at a time of an inoperative state, an analog audio signal which is output from a line-out-equipped external device (e.g. a portable audio player 25), and outputting the audio signal from speakers 18 which are mounted on the housing of the computer 10.

When the output from the audio player 25 is directly connected to the speakers, since the output of the audio player 25 is small, compared to the capability of the speakers, the speakers are unable to output sound of a sufficient volume. According to the audio output function that is provided in the personal computer 10 in this embodiment, even in the case where the personal computer 10 is in the inoperative state, power is supplied to a built-in amplifier for audio signal amplification, thus being able to amplify the audio signal from the audio player 25 and output the amplified audio signal from the speakers 18.

It is assumed that the “inoperative state” of the personal computer 10 includes states called “standby/sleep/suspend” (system state S3) and “hibernation” (hibernate state) (system state S4), as well as a power-off state (shut-down) (system state S5). In short, the inoperative state is a state in which the processor (CPU 30) does not operate. The power-on state is system state S0.

The personal computer 10 of this embodiment executes control to enable audio corresponding to an analog audio signal, which is output from the audio player 25, to be output even in the inoperative state, based on the connection/disconnection of the audio player 25 and the presence/absence of an audio signal which is output from the audio player 25.

FIG. 1 is a perspective view showing the state in which a display unit of the personal computer 10 is opened. The personal computer 10 comprises a computer main body 11 and a display unit 12. A display device, which is composed of an LCD (Liquid Crystal Display) 17, is built in the display unit 12. The display screen of the LCD 17 is disposed at a substantially central part of the display unit 12.

The display unit 12 is attached to the computer main body 11 such that the display unit 12 is rotatable between an open position and a closed position via a hinge mechanism 21. The computer main body 11 has a thin box-shaped housing, to which a battery is detachably attached.

A keyboard 13, a power button switch 14 for power-on/off, general-purpose hardware buttons 15, a touch pad 16, and speakers 18 are disposed on the top surface of the computer main body 11.

A side surface of the computer main body 11 is provided with a line-in terminal 19 (jack) for receiving an analog audio signal which is output from the audio player 25. A cable 26, which is connected to a line-out terminal of the audio player 25, can be connected to the line-in terminal 19 by a plug 27.

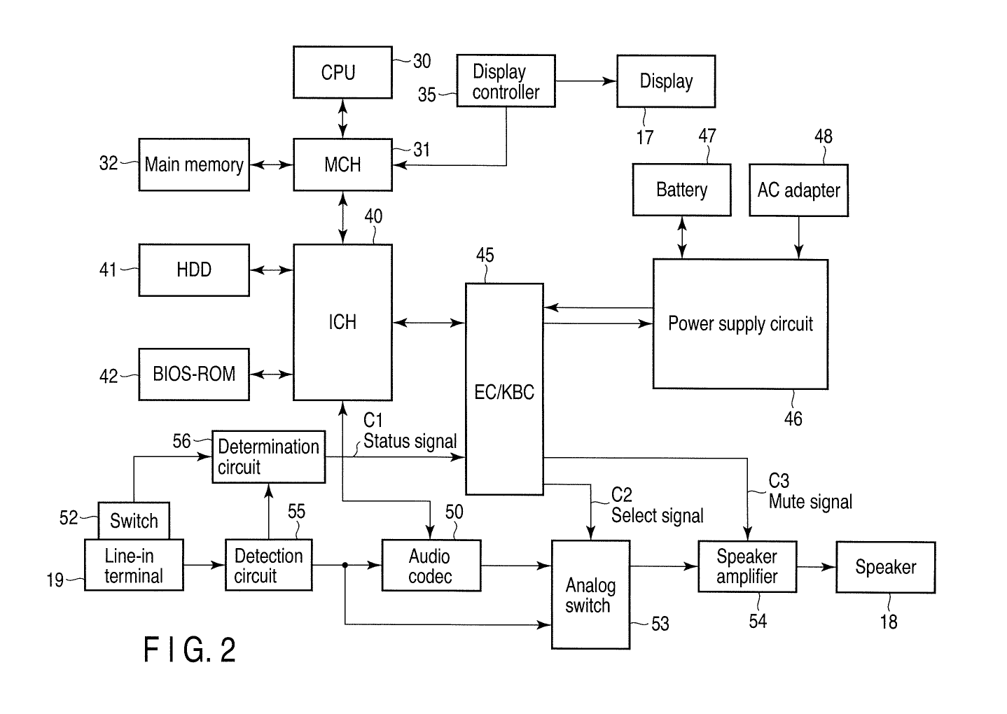

Next, referring to FIG. 2, a description is given of the system configuration of the personal computer 10 according to the embodiment.

The personal computer 10, as shown in FIG. 2, includes a CPU 30, an MCH 31 (north bridge), a main memory 32, a display controller 35, an ICH 40 (south bridge), a hard disk drive (HDD) 41, a BIOS-ROM 42, an embedded controller/keyboard controller IC (EC/KBC) 45, and a power supply circuit 46.

The CPU 30 is a processor which is provided in order to control the operation of the personal computer 10, and executes an operating system (OS), drivers for controlling various hardware, and various application programs, which are loaded from the HDD 41 into the main memory 32. The CPU 30 also executes a system BIOS (Basic Input/Output System) which is stored in the BIOS-ROM 42. The system BIOS is a program for hardware control.

The MCH 31 is a bridge device which connects a local bus of the CPU 30 and the ICH 40. The MCH 31 incorporates a memory controller for access-controlling the main memory 32.

The display controller 35 controls the LCD 17 which is used as a display monitor of the personal computer 10. Based on an image-rendering request which is sent from the CPU 30 via the MCH 31, the display controller 35 executes a display process (graphics arithmetic process) for rendering frames in a video memory (VRAM).

The ICH 40 incorporates an IDE (Integrated Drive Electronics) controller and a Serial ATA controller for controlling the HDD 41 and an optical disc drive (not shown).

The embedded controller/keyboard controller IC (EC/KBC) 45 is a one-chip microcomputer in which an embedded controller for power management and a keyboard controller for controlling the keyboard (KB) 13, touch pad 16 and general-purpose hardware buttons 18 are integrated.

The EC/KBC 45 has a function of controlling the power supply circuit 46 in accordance with an operation of the power button switch 14 by a user, and powering on/off the personal computer 10. The power-on/off control of the personal computer 10 is executed by the cooperation between the EC/KBC 45 and power supply circuit 46. In addition, the EC/KBC 45 is a module which is supplied with power even when the personal computer 10 is in any one of the system states including the inoperative state (power-off state). The EC/KBC 45 is used as a controller for controlling the audio output function (sleep & music function) which is used when the personal computer 10 is in the inoperative state. If a controller which is operable in the inoperative state is mounted, in addition to the EC/KBC 45, the audio output function may be controlled by this controller.

The power supply circuit 46 receives power from a battery 47 which is attached to the computer main body 11 or from an external power supply which is connected via an AC adapter 48, and generates and supplies operation power to the respective components. The power supply circuit 46 is provided with a power supply microcomputer. The power supply microcomputer monitors the power supply (charge/discharge) relating to the respective components and the battery, and the charging state of the battery.

The power supply circuit 46 controls the ON/OFF of the power supply to the respective modules by the control of the EC/KBC 45 according to the system state of the personal computer 10. In order to operate the audio output function (sleep & music function) when the personal computer 10 is in the inoperative state (system state S3, S4, S5), the power supply circuit 46 in the embodiment is provided with a power supply system for supplying power to the respective modules relating to the audio output function. By this power supply system, even when the personal computer 10 is in the inoperative state, power is supplied to an analog switch 53 and a speaker amplifier 54, which process an analog audio signal, and a detection circuit 55 and a determination circuit 56, which control the ON/OFF of the audio output function.

An audio codec 50 converts digital audio data, which is input via the ICH 40, to an analog audio signal, and outputs the analog audio signal to the analog switch 53 by adjusting a volume or a sound quality (sound effect) by the control of the OS, device driver, audio playback program, etc. Similarly, when the personal computer 10 is in the operative state, the audio codec 50 executes a signal process, such as volume control of an analog audio signal from the audio player 25, which is input via the line-in terminal 19, and outputs the resultant analog audio signal to the analog switch 53.

The analog switch 53 switches the path between the audio codec 50 side and the detection circuit 55 side, in accordance with a select signal S2 from the EC/KBC 45. Under the control of the EC/KBC 45, the analog switch 53 is changed over to the audio codec 50 side when the personal computer 10 is in the operative state. When the audio output function is enabled at the non-operation time, the audio codec 50 is switched over to the detection circuit 55 side.

The speaker amplifier 54 amplifies the analog audio signal which is input via the analog switch 53, and outputs sound corresponding to the audio signal from the speakers 18. In addition, in accordance with a mute signal S3 from the EC/KBC 45, the speaker amplifier 54 can switch mute/mute-release of audio.

A switch (or sensor) 52 is incorporated in the line-in terminal 19. The ON/OFF of the switch 52 is changed by the insertion of the plug 27 (connection member) for connection of the cable 26 to the line-in terminal 19, and the switch 52 outputs a detection signal corresponding to the ON/OFF state to the determination circuit 56.

The detection circuit 55 is provided between the line-in terminal 19 and the audio codec 50. The detection circuit 55 detects that an audio signal is input via the line-in terminal 19. The detection circuit 55 determines whether the audio signal is being input or not, for example, according to whether the audio signal that is input to the line-in terminal 19 is at a predetermined level or more. If the detection circuit 55 determines that the audio signal is at the predetermined level or more and that the audio signal is being input, and then if the audio signal decreases below the predetermined level for a predetermined period or more, the detection circuit determines that the audio signal is not input (for example, the playback of, e.g. music, in the audio player 25 is halted).

In addition, the detection circuit 55 detects whether the external device (audio player 25) is connected via the line-in terminal 19, based on the impedance between the line-in terminal 19 and the ground. The detection circuit 55 outputs to the determination circuit 56 a detection signal corresponding to a detection result as to whether the external device (audio player 25) is connected or not, and a detection result as to whether the audio signal is being input or not.

The determination circuit 56 is composed of, for example, a gate IC, and detects that the plug 27 is connected to the line-in terminal 19, in accordance with a detection signal from the line-in terminal 19. The determination circuit 56 outputs a status signal C1, which controls the ON/OFF of the audio output function, to the EC/KBC 45, in accordance with the detection signal from the line-in terminal 19 and the detection signal from the detection circuit 55.

Like the EC/KBC 45, the detection circuit 55 and determination circuit 56 are supplied with power in any one of the system states, in order to output signals for controlling the ON/OFF of the audio output function in the inoperative state.

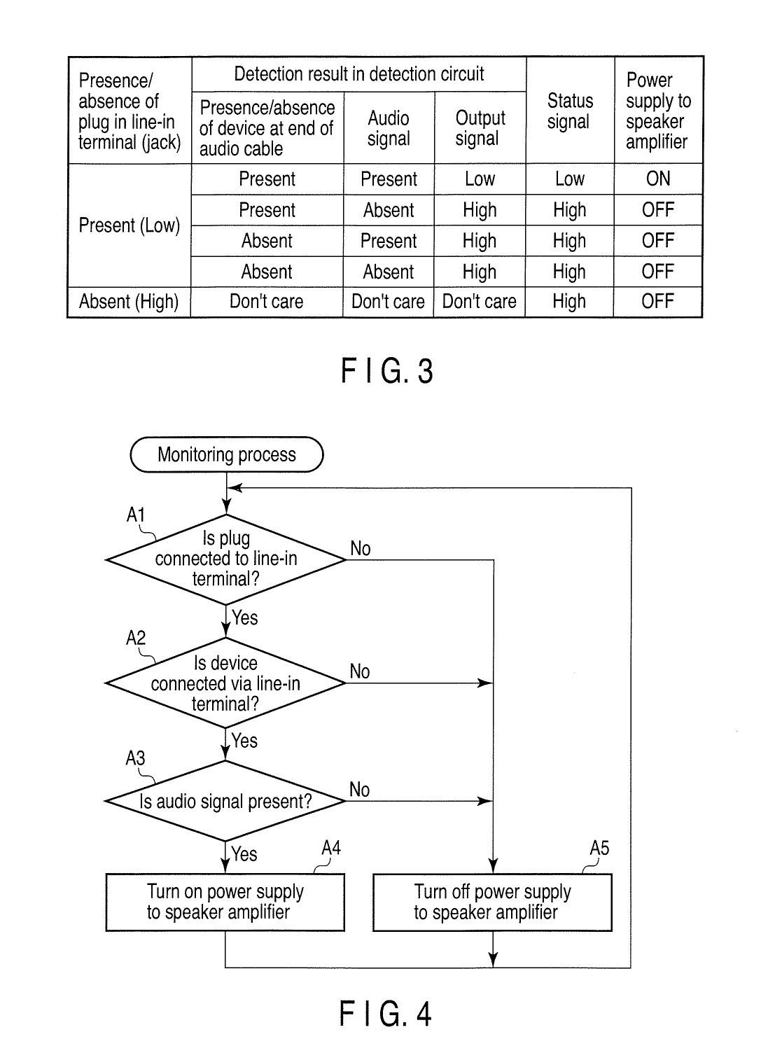

FIG. 3 is an exemplary view showing the relationship between the status signal C1, which is output from the determination circuit 56, and the ON/OFF of the audio output function (ON/OFF of power supply to the speaker amplifier 54).

The detection circuit 55 detects whether the external device is connected to the end of the cable of the plug 27 that is inserted in the line-in terminal 19, and detects, at the same time, whether the audio signal that is input from the line-in terminal 19 is present or not, and notifies the detection result. For example, the detection circuit 55 outputs, as the detection signal indicative of the notified result, a “Low” signal when the external device is connected to the end of the cable and the audio signal is present, and outputs a “High” signal in other cases.

The determination circuit 56 outputs the status signal C1 to the EC/KBC 45, in accordance with the detection signal from the detection circuit 55 and the signal state of the switch 52 that is incorporated in the line-in terminal 19.

The status signal C1, which is output from the determination circuit 56, is a “Low” signal only when the plug 27 is inserted in the line-in terminal 19, the external device (audio player 25) is connected to the end of the cable 26 via the plug 27, and the audio signal is detected, and is a “High” signal in other cases. After detecting that the status signal C1 is “Low”, the EC/KBC 45 turns on power supply from the power supply circuit 46 to the speaker amplifier 54.

Next, the operation of the personal computer 10 of the embodiment is described.

When the personal computer 10 is in the inoperative state (system state S3, S4, S5), the personal computer 10 causes the EC/KBC 45 to execute a monitoring process. The EC/KBC 45 is supplied with power even in the inoperative state, and executes the monitoring process for monitoring the power button switch 14 and monitoring the status signal C1 for controlling the ON/OFF of the audio output function.

When the user intends to output an audio signal, which is output from the audio player 25, from the speakers 18 by making use of the audio output function of the personal computer 10, the user inserts the plug 27 of the cable 26 in the line-in terminal 19, thereby connecting the personal computer 10 and the audio player 25. Then, the user presses, for example, a playback button of the audio player 25, and starts playback of music, etc.

The switch 52 outputs to the determination circuit 56 a “Low” signal which indicates that the plug 27 has been inserted in the line-in terminal 19. By the insertion of the plug 27 in the line-in terminal 19, the detection circuit 55 is electrically connected to the audio player 25. From the variation in impedance between the line-in terminal 19 and the ground, the detection circuit 55 detects that the audio player 25 has been connected.

In addition, if the detection circuit 55 detects that an audio signal of a preset level or more has been input by the playback of music, etc. in the audio player 25, the detection circuit 55 switches the signal to the determination circuit 56 from a “High” signal to a “Low” signal.

If the determination circuit 56 receives from the switch 52 a “Low” signal indicating that the plug 27 has been connected, and receives from the detection circuit 55 a “Low” signal indicating that the audio player 25 has been connected and the audio signal has been input, the determination circuit 56 outputs a status signal C1 (“Low” signal) for activating the audio output function to the EC/KBC 45.

If the EC/KBC 45 detects that the status signal C1 has changed to the “Low” signal, the EC/KBC 45 executes a process for activating the audio output function.

To begin with, the EC/KBC 45 sets the speaker amplifier 54 in a mute state by a mute signal S3. Specifically, since noise occurs when power is supplied to the speaker amplifier 54 or when the analog switch 53 is changed over, the speaker amplifier 54 is controlled to prevent the speakers 18 from producing sound.

After the speaker amplifier 54 is set in the mute state, the EC/KBC 45 causes the power supply circuit 46 to turn on power supply to the speaker amplifier 54 and the audio codec 50. Specifically, the speaker amplifier 54 and analog switch 53, which are associated with the audio output function, are rendered operable, while the personal computer 10 is kept in the inoperative state.

Since the audio codec 50 is controlled by the program, the audio codec 50 does not operate in the system state S3, S4 or S5. Thus, the EC/KBC 45 controls the analog switch 53 by the select signal S2, thereby switching the path so that the analog audio signal, which is input from the line-in terminal 19, may bypass the audio codec 50 and go to the speaker amplifier 54.

After the change-over of the analog switch 53 is completed, the EC/KBC 45 releases the mute state of the speaker amplifier 54 by the mute signal S3.

For example, an audio signal, which is input by the playback of music in the audio player 25, is input to the speaker amplifier 54 via the line-in terminal 19, detection circuit 55 and analog switch 53. Since the speaker amplifier 54 is supplied with power from the power supply circuit 46, the speaker amplifier 54 can amplify the analog audio signal and output the music from the speakers 18. At this time, in the personal computer 10, no power is supplied to the modules which are not associated with the audio output function. Therefore, the power consumption of the personal computer 10 can greatly be reduced, compared to the case in which the personal computer is in the power-on state.

If the plug 27 is detached from the line-in terminal 19 during the operation of the audio output function, the detection signal from the switch 52 to the determination circuit 56 indicates the disconnection. Accordingly, the determination circuit 56 outputs the status signal C1 (“High” signal), which turns off the audio output function, to the EC/KBC 45.

If the audio player 25 is detached from the cable 26 while the plug 27 is inserted in the line-in terminal 19, the detection circuit 55 detects, from the variation in impedance, that the audio player 25 is not connected. In this case, the detection circuit 55 outputs a “High” signal to the determination circuit 56. Accordingly, the determination circuit 56 outputs to the EC/KBC 45 the status signal (“High” signal) which turns off the audio output function.

In the state in which the audio player 25 is connected, if the time period, in which the level of the audio signal that is input from the line-in terminal 19 is less than the preset level, continues for a predetermined time period or more, the detection circuit 55 switches the detection signal to the determination circuit 56 from the “Low” signal to the “High” signal which indicates that the audio signal is not input. Accordingly, the determination circuit 56 outputs to the EC/KBC 45 the status signal C1 (“High” signal”) which turns off the audio output function.

Specifically, when the level of the audio signal that is input from the line-in terminal 19 is the preset level or more, the detection circuit 55 outputs the “Low” signal to the determination circuit 56, thus immediately enabling the audio output function. While the audio output function is being operated, even if the level of the audio signal decreases to below the preset level for a time period that is shorter than the predetermined time period, the detection circuit 55 does not output the “Low” signal, and thus the audio output function is not halted.

For example, even if the music, which is played back by the audio player 25, includes a part in which the output level of audio lowers in a short time, the ON/OFF of the audio output function is not frequently switched in accordance with the lowering of the output level. It is assumed that the predetermined time period for determining the level of the audio signal in the detection circuit 55 is set in the detection circuit 55 in advance.

In the above description, the detection circuit 55 determines whether the time period, in which the level of the audio signal is less than the preset level, continues for a predetermined time period or more. Alternatively, the detection circuit 55 may output the “Low” signal or “High” signal to the determination circuit 56, according to whether the level of the audio signal is the preset level or more. In this case, the EC/KBC 45 operates to halt the audio output function when a predetermined time period has passed since the change of the status signal C1, which is output from the determination circuit 56, from the “High” signal to the “Low” signal. Thereby, it becomes possible to prevent the ON/OFF of the audio output function from being frequently switched in accordance with the switching of the status signal C1.

In the case of determining whether the predetermined time period has passed since the change of the status signal C1 from the “High” signal to the “Low” signal, this predetermined time period may be set by the user. For example, when the personal computer 10 is operated, the utility program or setup program for BIOS setup, etc. are executed, and the predetermined time period up to the turn-off of the audio output function is designated by the user. The data indicative of the predetermined time period that has been set by the setup program is stored in the nonvolatile memory of the EC/KBC 45 before the personal computer 10 transitions to the inoperative state. Based on the stored data, the EC/KBC 45 determines whether the predetermined time period has passed since the change of the status signal C1 from the “High” signal to the “Low” signal, and controls the ON/OFF of the audio output function.

If the status signal C1 from the determination circuit 56 has changed to the “High” signal, the EC/KBC 45 executes the process for halting the audio output function.

In the case of halting the audio output function, the EC/KBC 45 sets the speaker amplifier 54 in the mute state by the mute signal C3.

After setting the speaker amplifier 54 in the mute state, the EC/KBC 45 controls the analog switch 53 by the select signal C2, and switches the path to the audio codec 50 side so that the analog audio signal, which is input from the line-in terminal 19, may go to the speaker amplifier 54 via the audio codec 50.

Thereafter, the EC/KBC 45 causes the power supply circuit 46 to turn off the power supply to the speaker amplifier 54 and analog switch 53. After completing the switching of the power supply, the EC/KBC 45 releases the mute state of the speaker amplifier 54 by the mute signal S3.

As has been described above, in the personal computer 10 of the embodiment, the audio output function is turned on if the plug 27 is inserted in the line-in terminal 19 in the inoperative state (system state S3, S4, S5) and the audio signal of the preset level or more is input from the audio player 25 which is connected via the line-in terminal 19.

Thus, when the plug 27 (cable 26) is simply connected to the line-in terminal 19, the audio output function is not activated. It is possible, therefore, to prevent such a situation that power supply to the speaker amplifier 54 is turned on and unnecessary power is consumed, despite the audio player 25, which outputs the audio signal, not being connected. Besides, when only the cable 26 is connected via the plug 27 (i.e. when the audio player 25 is disconnected from the cable 26), the metal terminal of the cable 26 for connection to the audio player 25 is exposed. Even if the user touches the metal terminal by the hand, for example, no unpleasant noise is produced from the speakers 18 since the audio output function is disabled.

Even if a plug other than the plug of the cable 26 for connecting the audio player 25, for instance, a plug for connecting headphones or a microphone, is inserted in the line-in terminal 19, the audio output function is not enabled unless the audio signal that is input from the line-in terminal 19 is at the preset level or more, and useless power consumption can be avoided in the state in which the audio output function is unnecessary.

In the above description, the condition under which the EC/KBC 45 activates the audio output function is that the status signal C1 that is output from the determination circuit 56 changes to the “Low” signal. However, the condition is not necessarily that the status signal C1 changes to the “Low” signal, and the condition may be determined according to the specifications of the EC/KBC 45. It should be noted, however, that the functions of the detection circuit 55 and determination circuit 56 are also determined according to the specifications of the EC/KBC 45.

In the above description, the EC/KBC 45 controls the ON/OFF of the audio output function is controlled in accordance with the status signal C1 that is output from the determination circuit 56. Alternatively, the EC/KBC 45 may be configured to include a functional module having the same functions as the detection circuit 55 and determination circuit 56, and may execute the monitoring process based on the determination result of this functional module. In this case, a signal line for inputting the audio signal, which is input via the line-in terminal 19, is connected to the EC/KBC 45, and also a signal line for inputting a detection signal from the switch 52 is connected to the EC/KBC 45.

FIG. 4 is an exemplary flow chart illustrating an operation in the case of executing the monitoring process in the EC/KBC 45.

If the personal computer 10 transitions to the inoperative state (system state S3, S4, S5), the EC/KBC 45 starts the monitoring process. The EC/KBC 45 is supplied with power even when the personal computer 10 is in the inoperative state. The EC/KBC 45 monitors the power button switch 14, and determines whether the present state is the state in which the audio output function is to be enabled or not, based on the detection signal from the switch 52 and the signal which is input via the line-in terminal 19.

If the EC/KBC 45 determines, based on the detection signal from the switch 52, that the plug 27 is not inserted in the line-in terminal 19 (No in block A1), the EC/KBC 45 does not activate the audio output function and causes the power supply circuit 46 to turn off power supply to the speaker amplifier 54 (block A5).

If the EC/KBC 45 determines that the plug 27 is inserted in the line-in terminal 19 (Yes in block A1), the EC/KBC 45 determines whether the external device (audio player 25) is connected via the line-in terminal 19, based on the impedance between the signal line from the line-in terminal and the ground. If the EC/KBC 45 determines that the external device is not connected, the EC/KBC 45 does not activate the audio output function and causes the power supply circuit 46 to turn off the power supply to the speaker amplifier 54 (block A5).

Further, if it is determined that the plug 27 is inserted in the line-in terminal 19 and that the external device (audio player 25) is connected via the line-in terminal 19, the EC/KBC 45 determines whether the level of the audio signal, which is input via the line-in terminal 19, is the preset level of more.

If it is determined that the level of the audio signal is not the preset level of more (No in block A3), the EC/KBC 45 does not activate the audio output function and causes the power supply circuit 46 to turn off the power supply to the speaker amplifier 54 (block A5).

On the other hand, if it is determined that the level of the audio signal is the preset level of more (Yes in block A3), the EC/KBC 45 EC/KBC 45 enables the audio output function. Specifically, the EC/KBC 45 controls the analog switch 53 by the select signal C2, switches the path of the audio signal, and controls the power supply circuit 46 to turn on power supply to the speaker amplifier 54. The process for activating the audio output function is executed in the same manner as described above, and a detailed description is omitted here.

In this manner, by providing the EC/KBC 45 with the functional module that is similar to the detection circuit 55 and determination circuit 56, the same advantageous effect as described above can be obtained.

In the block diagram of FIG. 2, the audio codec 50 and the speaker amplifier 54 are provided independently. Alternatively, the audio codec 50 may be configured such that the amplification function of the speaker amplifier 54 is integrated in the audio codec 50. In this case, when the audio output function is activated in the inoperative state, the power supply to the audio codec 50 is turned on by the control of the power supply circuit 46. In the inoperative state, the audio codec 50 receives the audio signal which is input via the line-in terminal 19, amplifies the received audio signal by the amplification function, and outputs the amplified audio signal to the speakers 18.

In the above-described embodiment, the personal computer 10 is used, by way of example, as the electronic apparatus. However, use may also be made of an electronic apparatus which has a speaker and to which an audio signal from the external device, such as the audio player 25, can be input.

The various modules of the systems described herein can be implemented as software applications, hardware and/or software modules, or components on one or more computers, such as servers. While the various modules are illustrated separately, they may share some or all of the same underlying logic or code.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An electronic apparatus comprising:
a speaker;
a terminal configured to connect an external device via a connection member, the external device outputting an audio signal;
a first detector configured to detect that the connection member is connected to the terminal;
a second detector configured to detect that the audio signal is received via the terminal;
an amplifier configured to amplify the audio signal and to produce sound from the speaker;
a power supply circuit configured to supply power to the amplifier; and
a controller configured to control the power supply circuit to supply power to the amplifier, when the first detector detects that the connection member is connected to the terminal, the second detector detects that the audio signal is received, and the electronic apparatus is in an inoperative state.

2. The electronic apparatus of claim 1, wherein the second detector is configured to detect whether the external device is connected to the terminal, based on an impedance between the terminal and a ground.

3. The electronic apparatus of claim 1, wherein the second detector is configured to detect that the audio signal is received, when a level of the audio signal is a preset level or more.

4. The electronic apparatus of claim 3, wherein the second detector is configured to detect that the audio signal is not received, when the level of the audio signal is less than the preset level for a predetermined time period or more.

5. The electronic apparatus of claim 1, wherein the controller comprises the first detector and the second detector, and is configured to be supplied with power from the power supply circuit when the electronic apparatus is in the inoperative state.

6. The electronic apparatus of claim 1, wherein the electronic apparatus is a notebook computer comprising:
a display unit and a main body comprising the speaker and a detector configured to detect whether the display unit is opened or closed to a predetermined degree or more.

7. A method of amplifying audio signal when an electronic device is in a non-operative state, comprising:
connecting a connection member to a terminal of the electronic device in the non-operative state, wherein the terminal is configured to receive an audio signal from an external device and the connection member is configured to connect to the external device,
detecting whether the connection member connected to the terminal,
detecting whether the audio signal is received via the terminal, and
supplying power to an amplifier when the connection member is connected to the terminal, the audio signal is received, and the electronic apparatus is in an inoperative state, wherein the amplifier is configured to amplify the audio signal received from the terminal and to output the amplified audio signal to the speaker.

8. The method of claim 7 further comprising detecting whether the external device is connected to the terminal, based on an impedance between the terminal and a ground.

9. The method of claim 7 further comprising detecting that the audio signal is received, when a level of the audio signal is a preset level or more.

10. The method of claim 9 further comprising detecting that the audio signal is not received, when the level of the audio signal is less than the preset level for a predetermined time period or more.
